(19) United States
(12) Patent Application Publication
(10) Pub. No.: US 2025/0347872 A1
(43) Pub. Date: Nov. 13, 2025

(54) OPTICAL DEVICE AND METHOD OF MANUFACTURE

(71) Applicant: Taiwan Semiconductor Manufacturing Co. Ltd., Hsinchu (TW)

(72) Inventor: Ming-Fa Chen, Taichung City (TW)

(21) Appl. No.: 19/278,438

(22) Filed: Jul. 23, 2025

Related U.S. Application Data
(63) Continuation of application No. 18/605,429, filed on Mar. 14, 2024.
(60) Provisional application No. 63/601,269, filed on Nov. 21, 2023.
(60) Provisional application No. 63/605,624, filed on Dec. 4, 2023.

(51) Int. Cl. G02B 6/42

(52) U.S. Cl. CPC G02B 6/424; G02B 6/4214; G02B 6/4244; G02B 6/428; G02B 6/4283

(57) ABSTRACT

Optical devices and methods of manufacture are presented in which a first connecting structure with a lens is utilized to transmit and receive optical signals to and from an optical device. In embodiments the first connecting structure comprises a first mirror and a lens aligned with the first mirror. The first mirror and the lens redirect optical signals into and out of the optical devices through an edge coupler within the optical device.

### PRIORITY CLAIM AND CROSS-REFERENCE

This application is a continuation of U.S. patent application Ser. No. 18/605,429, filed Mar. 14, 2024, which application claims the benefit of U.S. Provisional Application No. 63/601,269, filed on Nov. 21, 2023, and U.S. Provisional Application No. 63/605,624, filed on Dec. 4, 2023, which applications are hereby incorporated herein by reference.

### BACKGROUND

Electrical signaling and processing is one technique for signal transmission and processing. Optical signaling and processing have been used in increasingly more applications in recent years, particularly due to the use of optical fiber-related applications for signal transmission.

Optical signaling and processing are typically combined with electrical signaling and processing to provide full-fledged applications. For example, optical fibers may be used for long-range signal transmission, and electrical signals may be used for short-range signal transmission as well as processing and controlling. Accordingly, devices integrating long-range optical components and short-range electrical components are formed for the conversion between optical signals and electrical signals, as well as the processing of optical signals and electrical signals. Packages thus may include both optical (photonic) dies including optical devices and electronic dies including electronic devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-9 illustrate formation of a first optical package, in accordance with some embodiments.

FIGS. 10A-10B illustrate an attachment of a first connecting unit to the first optical package, in accordance with some embodiments.

FIG. 11 illustrates an attachment of an interposer substrate, in accordance with some embodiments.

FIG. 12 illustrates a top down view of the first optical package and first connecting unit, in accordance with some embodiments.

FIGS. 13A-13C illustrate a multi-level set of lenses, in accordance with some embodiments.

FIG. 14 illustrates a bonding of an electronic integrated circuit to the interposer substrate, in accordance with some embodiments.

FIGS. 15A-15C illustrate an attachment process with an encapsulant, in accordance with some embodiments.

FIG. 16 illustrates a flow chart of attaching the first connecting unit, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will now be discussed with respect to certain embodiments in which a mirror structure is utilized to route incoming and outgoing optical signals between an optical fiber and an edge coupler of a first optical package, forming a compact universal photonic engine (COUPE) package with an integrated optical port and lens/reflector module to form a COUPE-edge coupler (COUPE-EC) package on substrate. The embodiments presented, however, are intended to be illustrative and are not intended to limit the ideas presented to the precise embodiments described. Rather, the ideas presented may be incorporated into a wide variety of embodiments (including any suitable technology node such as a N3 or N5 technology node or any suitable wafer level process), and all such embodiments may be included within the overall scope of the disclosure.

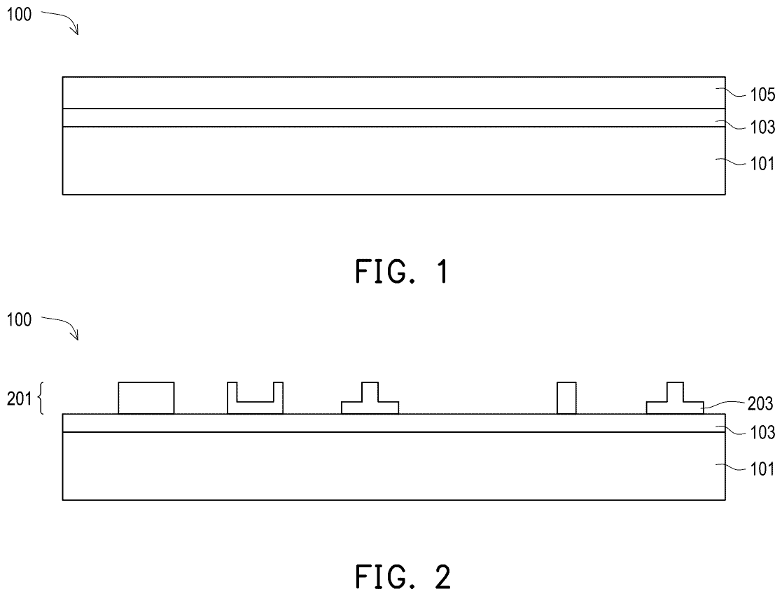

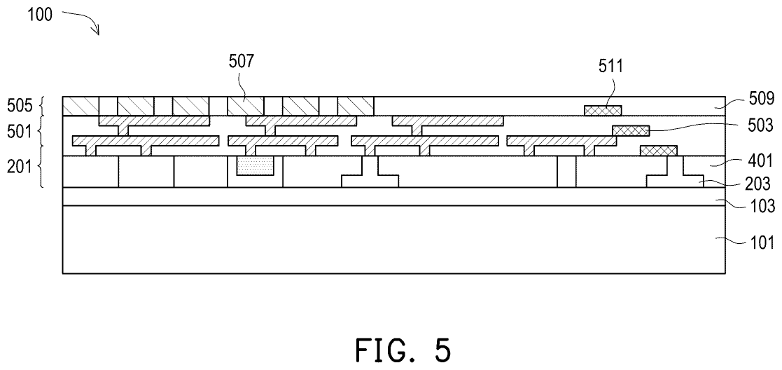

With reference now to FIG. 1, there is illustrated an initial structure of an optical interposer 100 (seen in FIG. 5), in accordance with some embodiments. In the particular embodiment illustrated in FIG. 1, the optical interposer 100 is a photonic integrated circuit (PIC) and comprises at this stage a first substrate 101, a first insulator layer 103, and a layer of material 105 for a first active layer 201 of first optical components 203 (not separately illustrated in FIG. 1 but illustrated and discussed further below with respect to FIG. 2). In an embodiment, at a beginning of the manufacturing process of the optical interposer 100, the first substrate 101, the first insulator layer 103, and the layer of material 105 for the first active layer 201 of first optical components 203 may collectively be part of a silicon-on-insulator (SOI) substrate. Looking first at the first substrate 101, the first substrate 101 may be a semiconductor material such as silicon or germanium, a dielectric material such as glass, or any other suitable material that allows for structural support of overlying devices.

The first insulator layer 103 may be a dielectric layer that separates the first substrate 101 from the overlying first active layer 201 and can additionally, in some embodiments, serve as a portion of cladding material that surrounds the subsequently manufactured first optical components 203 (discussed further below). In an embodiment the first insulator layer 103 may be silicon oxide, silicon nitride, germanium oxide, germanium nitride, combinations of these, or the like, formed using a method such as implantation (e.g., to form a buried oxide (BOX) layer) or else may be deposited onto the first substrate 101 using a deposition method such as chemical vapor deposition, atomic layer deposition, physical vapor deposition, combinations of these, or the like. However, any suitable material and method of manufacture may be used.

The material 105 for the first active layer 201 is initially (prior to patterning) a conformal layer of material that will be used to begin manufacturing the first active layer 201 of the first optical components 203. In an embodiment the material 105 for the first active layer 201 may be a translucent material that can be used as a core material for the desired first optical components 203, such as a semiconductor material such as silicon, germanium, silicon germanium, combinations of these, or the like, while in other embodiments the material 105 for the first active layer 201 may be a dielectric material such as silicon nitride or the like, although in other embodiments the material 105 for the first active layer 201 may be III-V materials, lithium niobate materials, or polymers. In embodiments in which the material 105 of the first active layer 201 is deposited, the material 105 for the first active layer 201 may be deposited using a method such as epitaxial growth, chemical vapor deposition, atomic layer deposition, physical vapor deposition, combinations of these, or the like. In other embodiments in which the first insulator layer 103 is formed using an implantation method, the material 105 of the first active layer 201 may initially be part of the first substrate 101 prior to the implantation process to form the first insulation layer 103. However, any suitable materials and methods of manufacture may be utilized to form the material 105 of the first active layer 201.

FIG. 2 illustrates that, once the material 105 for the first active layer 201 is ready, the first optical components 203 for the first active layer 201 are manufactured using the material 105 for the first active layer 201. In embodiments the first optical components 203 of the first active layer 201 may include such components as optical waveguides (e.g., ridge waveguides, rib waveguides, buried channel waveguides, diffused waveguides, etc.), couplers (e.g., grating couplers, edge couplers that are a narrowed waveguide with a width of between about 1 nm and about 200 nm, etc.), directional couplers, optical modulators (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like. However, any suitable first optical components 203 may be used.

To begin forming the first active layer 201 of first optical components 203 from the initial material, the material 105 for the first active layer 201 may be patterned into the desired shapes for the first active layer 201 of first optical components 203. In an embodiment the material 105 for the first active layer 201 may be patterned using, e.g., one or more photolithographic masking and etching processes. However, any suitable method of patterning the material 105 for the first active layer 201 may be utilized. For some of the first optical components 203, such as waveguides or edge couplers, the patterning process may be all or at least most of the manufacturing that is used to form these first optical components 203.

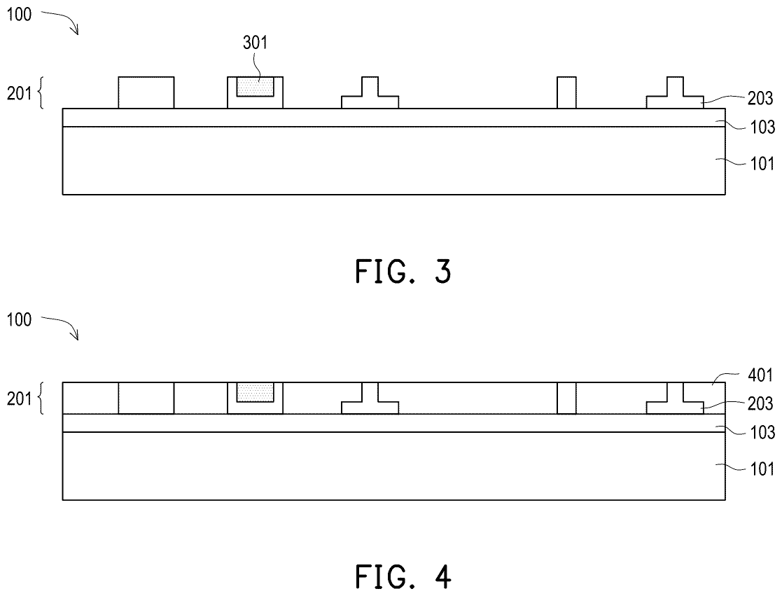

FIG. 3 illustrates that, for those components that utilize further manufacturing processes, such as Mach-Zehnder silicon-photonic switches that utilize resistive heating elements, additional processing may be performed either before or after the patterning of the material for the first active layer 201. For example, implantation processes, additional deposition and patterning processes for different materials (e.g., resistive heating elements, III-V materials for converters), combinations of all of these processes, or the like, can be utilized to help further the manufacturing of the various desired first optical components 203. In a particular embodiment, and as specifically illustrated in FIG. 3, in some embodiments an epitaxial deposition of a semiconductor material 301 such as germanium (used, e.g., for electricity/optics signal modulation and transversion) may be performed on a patterned portion of the material 105 of the first active layer 201. In such an embodiment the semiconductor material 301 may be epitaxially grown in order to help manufacture, e.g., a photodiode for an optical-to-electrical converter. All such manufacturing processes and all suitable first optical components 203 may be manufactured, and all such combinations are fully intended to be included within the scope of the embodiments.

FIG. 4 illustrates that, once the individual first optical components 203 of the first active layer 201 have been formed, a second insulator layer 401 may be deposited to cover the first optical components 203 and provide additional cladding material. In an embodiment the second insulator layer 401 may be a dielectric layer that separates the individual components of the first active layer 201 from each other and from the overlying structures and can additionally serve as another portion of cladding material that surrounds the first optical components 203. In an embodiment the second insulator layer 401 may be silicon oxide, silicon nitride, germanium oxide, germanium nitride, combinations of these, or the like, formed using a deposition method such as chemical vapor deposition, atomic layer deposition, physical vapor deposition, combinations of these, or the like. Once the material of the second insulator layer 401 has been deposited, the material may be planarized using, e.g., a chemical mechanical polishing process in order to either planarize a top surface of the second insulator layer 401 (in embodiments in which the second insulator layer 401 is intended to fully cover the first optical components 203) or else planarize the second insulator layer 401 with top surfaces of the first optical components 203. However, any suitable material and method of manufacture may be used.

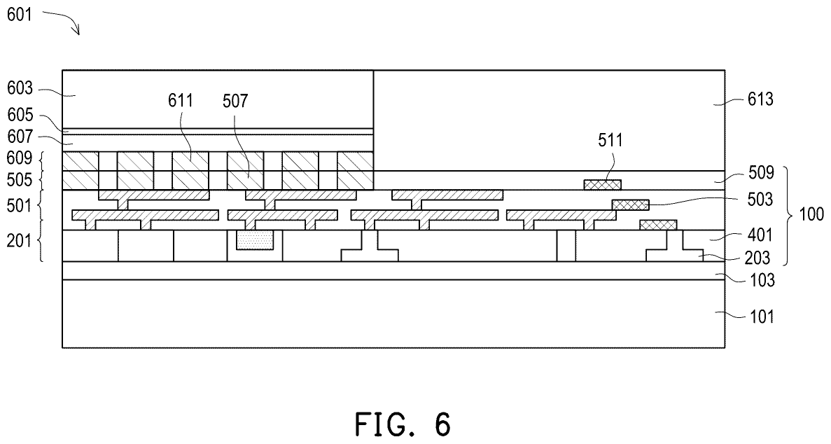

FIG. 5 illustrates that, once the first optical components 203 of the first active layer 201 have been manufactured and the second insulator layer 401 has been formed, first metallization layers 501 are formed in order to electrically connect the first active layer 201 of first optical components 203 to control circuitry, to each other, and to subsequently attached devices (not illustrated in FIG. 5 but illustrated and described further below with respect to FIG. 6). In an embodiment the first metallization layers 501 are formed of alternating layers of dielectric and conductive material and may be formed through any suitable processes (such as deposition, damascene, dual damascene, etc.). In particular embodiments there may be multiple layers of metallization used to interconnect the various first optical components 203, but the precise number of first metallization layers 501 is dependent upon the design of the optical interposer 100.

Additionally, during the manufacture of the first metallization layers 501, one or more second optical components 503 may be formed as part of the first metallization layers 501. In some embodiments the second optical components 503 of the first metallization layers 501 may include such components as couplers (e.g., edge couplers, grating couplers, etc.) for connection to outside signals, optical waveguides (e.g., ridge waveguides, rib waveguides, buried channel waveguides, diffused waveguides, etc.), optical modulators (e.g., Mach-Zehnder silicon-photonic switches, microelectromechanical switches, micro-ring resonators, etc.), amplifiers, multiplexors, demultiplexors, optical-to-electrical converters (e.g., P-N junctions), electrical-to-optical converters, lasers, combinations of these, or the like. However, any suitable optical components may be used for the one or more second optical components 503.

In an embodiment the one or more second optical components 503 may be formed by initially depositing a material for the one or more second optical components 503. In an embodiment the material for the one or more second optical components 503 may be a dielectric material such as silicon nitride, silicon oxide, combinations of these, or the like, or a semiconductor material such as silicon, deposited using a deposition method such as chemical vapor deposition, atomic layer deposition, physical vapor deposition, combinations of these, or the like. However, any suitable material and any suitable method of deposition may be utilized.

Once the material for the one or more second optical components 503 has been deposited or otherwise formed, the material may be patterned into the desired shapes for the one or more second optical components 503. In an embodiment the material of the one or more second optical components 503 may be patterned using, e.g., one or more photolithographic masking and etching processes. However, any suitable method of patterning the material for the one or more second optical components 503 may be utilized.

For some of the one or more second optical components 503, such as waveguides or edge couplers, the patterning process may be all or at least most manufacturing that is used to form these components. Additionally, for those components that utilize further manufacturing processes, such as Mach-Zehnder silicon-photonic switches that utilize resistive heating elements, additional processing may be performed either before or after the patterning of the material for the one or more second optical components 503. For example, implantation processes, additional deposition and patterning processes for different materials, combinations of all of these processes, or the like, and can be utilized to help further the manufacturing of the various desired one or more second optical components 503. All such manufacturing processes and all suitable one or more second optical components 503 may be manufactured, and all such combinations are fully intended to be included within the scope of the embodiments.

Once the one or more second optical components 503 of the first metallization layers 501 have been manufactured, a first bonding layer 505 is formed over the first metallization layers 501. In an embodiment, the first bonding layer 505 may be used for a dielectric-to-dielectric and metal-to-metal bond. In accordance with some embodiments, the first bonding layer 505 is formed of a first dielectric material 509 such as silicon oxide, silicon nitride, or the like. The first dielectric material 509 may be deposited using any suitable method, such as CVD, high-density plasma chemical vapor deposition (HDPCVD), PVD, atomic layer deposition (ALD), or the like. However, any suitable materials and deposition processes may be utilized.

Once the first dielectric material 509 has been formed, first openings in the first dielectric material 509 are formed to expose conductive portions of the underlying layers in preparation to form first bond pads 507 within the first bonding layer 505. Once the first openings have been formed within the first dielectric material 509, the first openings may be filled with a seed layer and a plate metal to form the first bond pads 507 within the first dielectric material 509. The seed layer may be blanket deposited over top surfaces of the first dielectric material 509 and the exposed conductive portions of the underlying layers and sidewalls of the openings and the second openings. The seed layer may comprise a copper layer. The seed layer may be deposited using processes such as sputtering, evaporation, or plasma-enhanced chemical vapor deposition (PECVD), or the like, depending upon the desired materials. The plate metal may be deposited over the seed layer through a plating process such as electrical or electro-less plating. The plate metal may comprise copper, a copper alloy, or the like. The plate metal may be a fill material. A barrier layer (not separately illustrated) may be blanket deposited over top surfaces of the first dielectric material 509 and sidewalls of the openings and the second openings before the seed layer. The barrier layer may comprise titanium, titanium nitride, tantalum, tantalum nitride, or the like.

Following the filling of the first openings, a planarization process, such as a CMP, is performed to remove excess portions of the seed layer and the plate metal, forming the first bond pads 507 within the first bonding layer 505. In some embodiments a bond pad via (not separately illustrated) may also be utilized to connect the first bond pads 507 with underlying conductive portions and, through the underlying conductive portions, connect the first bond pads 507 with the first metallization layers 501.

Additionally, the first bonding layer 505 may also include one or more third optical components 511 incorporated within the first bonding layer 505. In such an embodiment, prior to the deposition of the first dielectric material 509, the one or more third optical components 511 may be manufactured using similar methods and similar materials as the one or more second optical components 503 (described above), such as by being waveguides and other structures formed at least in part through a deposition and patterning process. However, any suitable structures, materials and any suitable methods of manufacture may be utilized.

FIG. 6 illustrates a bonding of a first semiconductor device 601 to the first bonding layer 505 of the optical interposer 100. In some embodiments, the first semiconductor device 601 is an electronic integrated circuit (EIC—e.g., a device without optical devices) and may have a semiconductor substrate 603, a layer of active devices 605, an overlying interconnect structure 607, a second bonding layer 609, and associated third bond pads 611. In an embodiment the semiconductor substrate 603 may be similar to the first substrate 101 (e.g., a semiconductor material such as silicon or silicon germanium), the active devices 605 may be transistors, capacitors, resistors, and the like formed over the semiconductor substrate 603, the interconnect structure 607 may be similar to the first metallization layers 501 (without optical components), the second bonding layer 609 may be similar to the first bonding layer 505, and the third bond pads 611 may be similar to the first bond pads 507. However, any suitable devices may be utilized.

In an embodiment the first semiconductor device 601 may be configured to work with the optical interposer 100 for a desired functionality. In some embodiments the first semiconductor device 601 may be a high bandwidth memory (HBM) module, an xPU, a logic die, a 3DIC die, a CPU, a GPU, a SoC die, a MEMS die, combinations of these, or the like. Any suitable device with any suitable functionality, may be used, and all such devices are fully intended to be included within the scope of the embodiments.

In an embodiment the first semiconductor device 601 and the first bonding layer 505 may be bonded using a dielectric-to-dielectric and metal-to-metal bonding process. In a particular embodiment which utilizes a dielectric-to-dielectric and metal-to-metal bonding process, the process may be initiated by activating the surfaces of the second bonding layer 609 and the surfaces of the first bonding layer 505. Activating the top surfaces of the first bonding layer 505 and the second bonding layer 609 may comprise a dry treatment, a wet treatment, a plasma treatment, exposure to an inert gas plasma, exposure to H₂, exposure to N₂, exposure to O₂, combinations thereof, or the like, as examples. In embodiments where a wet treatment is used, an RCA cleaning may be used, for example. In another embodiment, the activation process may comprise other types of treatments. The activation process assists in the bonding of the first bonding layer 505 and the second bonding layer 609.

After the activation process the optical interposer 100 and the first semiconductor device 601 may be cleaned using, e.g., a chemical rinse, and then the first semiconductor device 601 is aligned and placed into physical contact with the optical interposer 100. The optical interposer 100 and the first semiconductor device 601 are then subjected to thermal treatment and contact pressure to bond the optical interposer 100 and first semiconductor device 601. For example, the optical interposer 100 and the first semiconductor device 601 may be subjected to a pressure of about 200 kPa or less, and a temperature between about 25° C. and about 250° C. to fuse the optical interposer 100 and the first semiconductor device 601. The optical interposer 100 and the first semiconductor device 601 may then be subjected to a temperature at or above the eutectic point for material of the first bond pads 507 and the third bond pads 611, e.g., between about 150° C. and about 650° C., to fuse the metal. In this manner, the optical interposer 100 and the first semiconductor device 601 forms a dielectric-to-dielectric and metal-to-metal bonded device. In some embodiments, the bonded dies are subsequently baked, annealed, pressed, or otherwise treated to strengthen or finalize the bond.

Additionally, while specific processes have been described to initiate and strengthen the bonds, these descriptions are intended to be illustrative and are not intended to be limiting upon the embodiments. Rather, any suitable combination of baking, annealing, pressing, or combination of processes may be utilized. All such processes are fully intended to be included within the scope of the embodiments.

FIG. 6 additionally illustrates that, once the first semiconductor device 601 has been bonded, a first gap-fill material 613 is deposited in order to fill the space around the first semiconductor device 601 and provide additional support. In an embodiment the first gap-fill material 613 may be a material such as silicon oxide, silicon nitride, silicon oxynitride, combinations of these, or the like, deposited to fill and overfill the spaces around the first semiconductor device 601. However, any suitable material and method of deposition may be utilized.

Once the first gap-fill material 613 has been deposited, the first gap-fill material 613 may be planarized in order to expose the first semiconductor device 601. In an embodiment the planarization process may be a chemical mechanical planarization process, a grinding process, or the like. However, any suitable planarization process may be utilized.

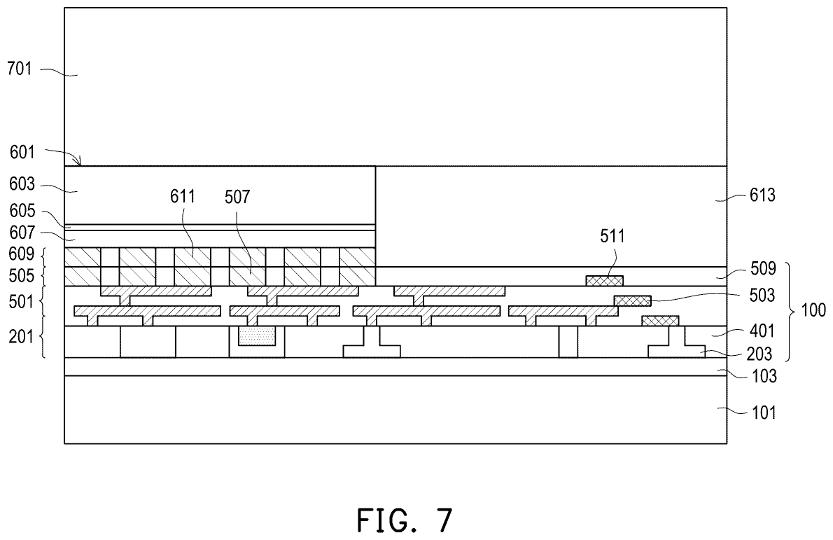

FIG. 7 illustrates an attachment of a first support substrate 701 to the first semiconductor device 601 and the first gap-fill material 613. In an embodiment the first support substrate 701 may be a support material that is transparent to the wavelength of light that is desired to be used, such as silicon, and may be attached using, e.g., an adhesive (not separately illustrated in FIG. 7). However, in other embodiments the first support substrate 701 may be bonded to the first semiconductor device 601 and the first gap-fill material 613 using, e.g., a bonding process. Any suitable method of attaching the first support substrate 701 may be used.

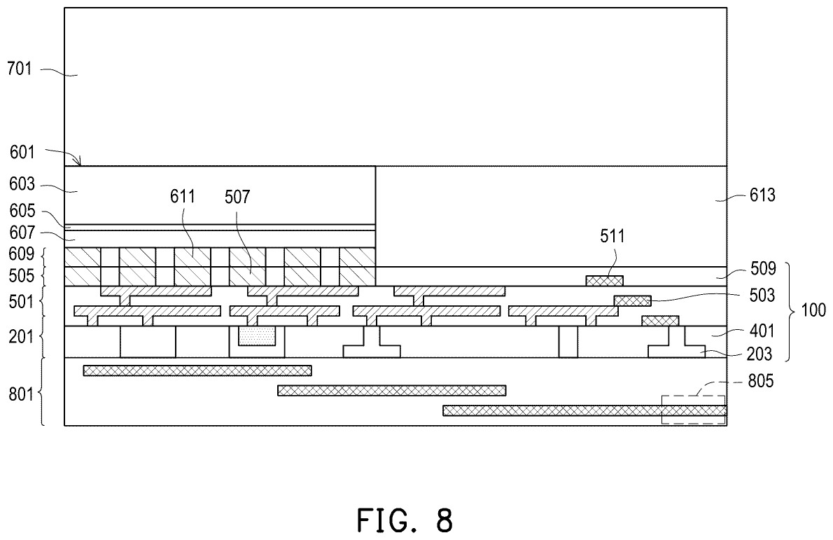

FIG. 8 illustrates a removal of the first substrate 101 and, optionally, the first insulator layer 103, thereby exposing the first active layer 201 of first optical components 203. In an embodiment the first substrate 101 and the first insulator layer 103 may be removed using a planarization process, such as a chemical mechanical polishing process, a grinding process, one or more etching processes, combinations of these, or the like. However, any suitable method may be used in order to remove the first substrate 101 and/or the first insulator layer 103.

Once the first substrate 101 and the first insulator layer 103 have been removed, a second active layer 801 of fourth optical components 803 may be formed on a back side of the first active layer 201. In an embodiment the second active layer 801 of fourth optical components 803 may be formed using similar materials and similar processes as the second optical components 503 of the first metallization layers 501 (described above with respect to FIG. 5). For example, the second active layer 801 of fourth optical components 803 may be formed of alternating layers of a cladding material such as silicon oxide and core material such as silicon nitride formed using deposition and patterning processes in order to form optical components such as waveguides and the like.

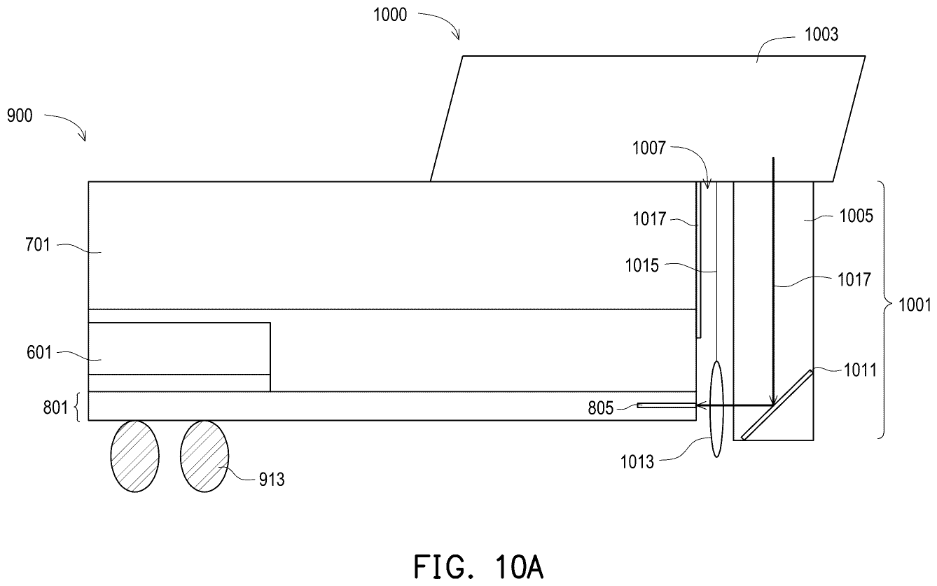

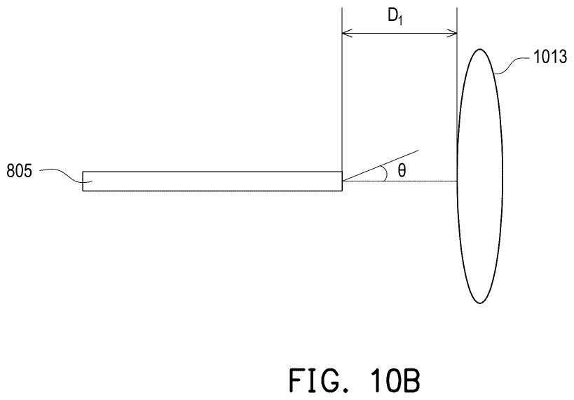

Additionally, in an embodiment the fourth optical components 803 of the second active layer 801 may comprise optical couplers in order to receive and transmit optical signals 1017 (not seen in FIG. 8 but illustrated and discussed further below in FIG. 10A) into and out of the second active layer 801. For example, the fourth optical components 803 may comprise one or more edge couplers (represented by the dashed box labeled 805 in FIG. 8). The one or more first edge couplers 805 may comprise one or more levels of edge couplers, wherein each level of first edge couplers 805 provide multiple optical paths, such as between about 20 and 80 optical paths, such as 40 optical paths). However, any suitable coupler may be utilized.

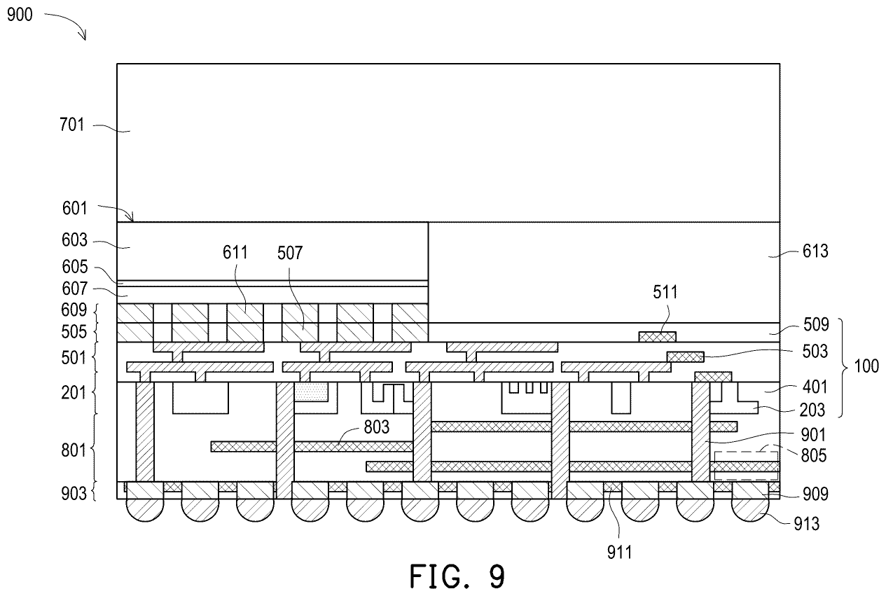

FIG. 9 illustrates formation of first through device vias (TDVs) 901 and formation of a third bonding layer 903 to form a first optical package 900 which, in some embodiments is a compact universal photonic engine (COUPE). In an embodiment the first through device vias 901 extend through the second active layer 801 and the first active layer 201 so as to provide a quick passage of power, data, and ground through the optical interposer 100. In an embodiment the first through device vias 901 may be formed by initially forming through device via openings into the optical interposer 100. The through device via openings may be formed by applying and developing a suitable photoresist (not shown), and removing portions of the second active layer 801 and the optical interposer 100 that are exposed.

Once the through device via openings have been formed within the optical interposer 100, the through device via openings may be lined with a liner. The liner may be, e.g., an oxide formed from tetraethylorthosilicate (TEOS) or silicon nitride, although any suitable dielectric material may alternatively be used. The liner may be formed using a plasma enhanced chemical vapor deposition (PECVD) process, although other suitable processes, such as physical vapor deposition or a thermal process, may also be used.

Once the liner has been formed along the sidewalls and bottom of the through device via openings, a barrier layer (also not independently illustrated) may be formed and the remainder of the through device via openings may be filled with first conductive material. The first conductive material may comprise copper, although other suitable materials such as aluminum, alloys, doped polysilicon, combinations thereof, and the like, may be utilized. The first conductive material may be formed by electroplating copper onto a seed layer (not shown), filling and overfilling the through device via openings. Once the through device via openings have been filled, excess liner, barrier layer, seed layer, and first conductive material outside of the through device via openings may be removed through a planarization process such as chemical mechanical polishing (CMP), although any suitable removal process may be used.

Optionally, in some embodiments once the first through device vias 901 have been formed, second metallization layers (not separately illustrated in FIG. 9) may be formed in electrical connection with the first through device vias 901. In an embodiment the second metallization layers may be formed as described above with respect to the first metallization layers 501, such as being alternating layers of dielectric and conductive materials using damascene processes, dual damascene process, or the like. In other embodiments, the second metallization layers may be formed using a plating process to form and shape conductive material, and then cover the conductive material with a dielectric material. However, any suitable structures and methods of manufacture may be utilized.

The third bonding layer 903 is formed in order to provide electrical connections between the optical interposer 100 and subsequently attached devices. In an embodiment the third bonding layer 903 may be similar to the first bonding layer 505, such as having third bond pads 909 (similar to the first bond pads 507) and even fifth optical components 911 (similar to the third optical components 511). However, any suitable devices may be utilized.

FIG. 9 additionally illustrates a placement of first external connectors 913 which may be formed to provide conductive regions for contact between the third bond pads 909 to other external devices. The first external connectors 913 may be conductive bumps (e.g., C4 bumps, ball grid arrays, microbumps, etc.) or conductive pillars utilizing materials such as solder and copper. In an embodiment in which the first external connectors 913 are contact bumps, the first external connectors 913 may comprise a material such as tin, or other suitable materials, such as silver, lead-free tin, or copper. In an embodiment in which the first external connectors 913 are tin solder bumps, the first external connectors 913 may be formed by initially forming a layer of tin through such commonly used methods such as evaporation, electroplating, printing, solder transfer, ball placement, etc. Once a layer of tin has been formed on the structure, a reflow may be performed in order to shape the material into the desired bump shape.

Of course, while the use of first external connectors 913 is one embodiment which may be used in order to provide connections for the first optical package 900, this is intended to be illustrative and is not intended to limit the embodiments. Rather, any suitable method of physically, electrically, and in some cases optically connecting the first optical package 900, such as dielectric-to-dielectric and metal-to-metal bonding, may also be utilized. Any suitable method of bonding the first optical package 900 may be used.

FIG. 10A illustrates mounting of a first connecting unit 1000 onto the first optical package 900. In an embodiment the first connecting unit 1000 comprises a first fiber array unit 1003 and a first lens reflector module (LRM) 1001, wherein the first fiber array unit 1003 provides an ingress and egress to optical signals 1017 to the first optical package 900. In an embodiment the first fiber array unit 1003 comprises a fiber array substrate material such as glass, a plastic material, or air (in cases in which there is an outer shell material—not separately illustrated). However, any suitable material may be utilized.

Within the fiber array substrate material a plurality of openings are formed for alignment of the individual optical fibers. The individual optical fibers are placed into the individual openings and, if desired, may be cleaved. In a particular embodiment the optical fibers may be cleaving using a process such as laser cleaving. However, any suitable process may be utilized to cleave the optical fibers.

The first lens reflector module 1001 is attached to the first fiber array unit 1003. In an embodiment the first lens reflector module 1001 comprises a supporting structure 1005 and a space 1007 is formed or located between the supporting structure 1005 and the first optical package 900 after the first lens reflector module 1001 is placed. In an embodiment the supporting structure 1005 comprises a similar material as the fiber array substrate material, such as being a transparent medium such as glass, a plastic material, silicon, metal, or any other suitable, transparent material, and may either be formed integrally with the fiber array substrate material or else may be formed separately and attached to the first fiber array unit 1003.

The space 1007 is formed or located between the supporting structure 1005 and the first optical package 900 in order to allow for the location of a first lens 1013 (described further below). In an embodiment the space 1007 may be formed by simply placing the first connecting unit 1000 so that the supporting structure 1005 is located a distance away from a sidewall of the first optical package 900.

Optionally, in some embodiments the space 1007 may be formed using the help of a case 1017. In an embodiment the case 1017 may enclose the space 1007 so that when the first connecting unit 1000 is being placed, the case 1017 provide an easy positioning of the space 1007. The case 1017 may be formed using a material such as glass, although any suitable material may be used.

A first mirror 1011 and/or other lenses (not separately illustrated) is located within the supporting structure 1005. The first mirror 1011 or lens may either be placed or else formed within the supporting structure 1005. In an embodiment the first mirror 1011 may comprise one or more single mirrors or may comprise a series of one or more mirrors (only one of which is illustrated in the cross-sectional view of FIG. 10A) that are part of an integral structure. In some embodiments the first mirror 1011 may be a 45° mirror or prism, although any suitable orientation may be utilized.

In an embodiment in which the first mirror 1011 is pre-formed, the first mirror 1011 may be placed and adhered into one or more openings located within the supporting structure 1005. Any suitable method of placing and holding the first mirror 1011 may be used.

In an embodiment in which the first mirror 1011 is formed within the supporting structure 1005 the first mirror 1011 may be formed by initially patterning the supporting structure 1005 to form a recess. In an embodiment the recess may be formed using one or more photolithographic masking and etching processes, such as one or more wet etching processes or dry etching processes. However, any suitable process may be utilized.

Once the recess has been formed, the first mirror 1011 may be formed along sidewalls of the recess. In an embodiment the first mirror 1011 may be a single layer of a reflective material such as aluminum copper, copper, gold, aluminum, titanium nitride, combinations of these, or the like, or else may be a multi-layer structure such as a Braggs reflector comprising alternating layers of different materials, such as alternating layers of silicon dioxide and amorphous silicon. The individual materials of the first mirror 1011 may be deposited using any suitable methods, such as chemical vapor deposition, physical vapor deposition, plating, combinations of these, or the like, and the individual layers may be then be further patterned using, e.g., a photolithographic masking and etching process (for example, to remove horizontal portions of the deposited materials). However, any suitable materials and methods may be utilized in order to form the first mirror 1011 along the sidewalls of the recess.

Additionally, if the formation of the first mirror 1011 does not fully fill the recess, the recess may be filled and planarized. In an embodiment the recess may be filled and/or overfilled with a material similar to the supporting structure 1005 deposited using a method such as chemical vapor deposition, followed by a planarization process such as a chemical mechanical polishing process. However, any suitable material and any suitable process may be utilized.

The first lens 1013 is placed within the space 1007 and positioned to modulate the optical signals 1017 between the first mirror 1011 and the first optical package 900. In an embodiment the first lens 1013 may be formed using a material such as silicon, glass, combinations of these, or the like. Additionally, the first lens 1013 may be formed to have a diameter of at least twice the mode field diameter (e.g., about 9.8 μm) of the waveguides of the first edge coupler 805. However, any suitable material, combinations of materials, and dimensions may be utilized.

In an embodiment the first lens 1013 may be accommodated within the glass case of the first connecting unit 1000, arranged along the Y axis, and overhung in parallel from the ceiling of the space 1007 with the use of a connection rod 1015. In an embodiment the connection rod 1015 may be a similar material as the fiber array substrate material, such as being a transparent medium such as glass or a plastic material and may either be formed integrally with the fiber array substrate material or else may be formed separately and attached to the first fiber array unit 1003. In other embodiments the connection rod may be a separate material and may be connected to the first fiber array unit 1003 with, e.g., an adhesive. Any suitable material and any suitable method of attachment may be utilized for the connection rod 1015.

The first lens 1013 may be connected to the connection rod 1015 and placed within the space 1007, where it is surrounded by the ambient environment such as air. In an embodiment the first lens 1013 may be connected using, e.g., an adhesive material such as a glue (not separately illustrated). However, any suitable material and method of attachment may be utilized.

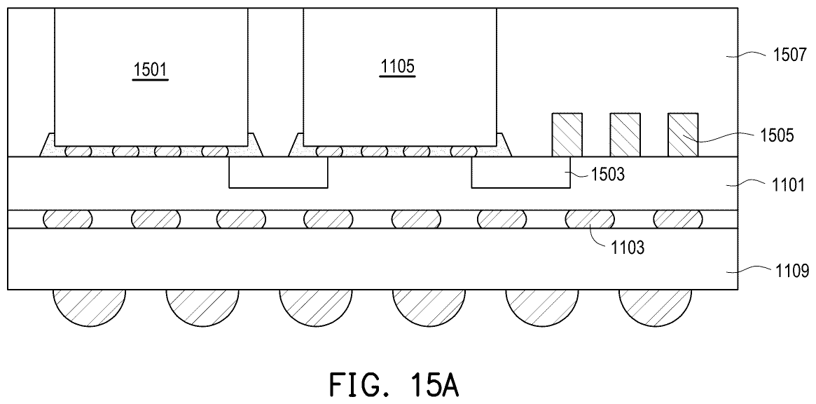

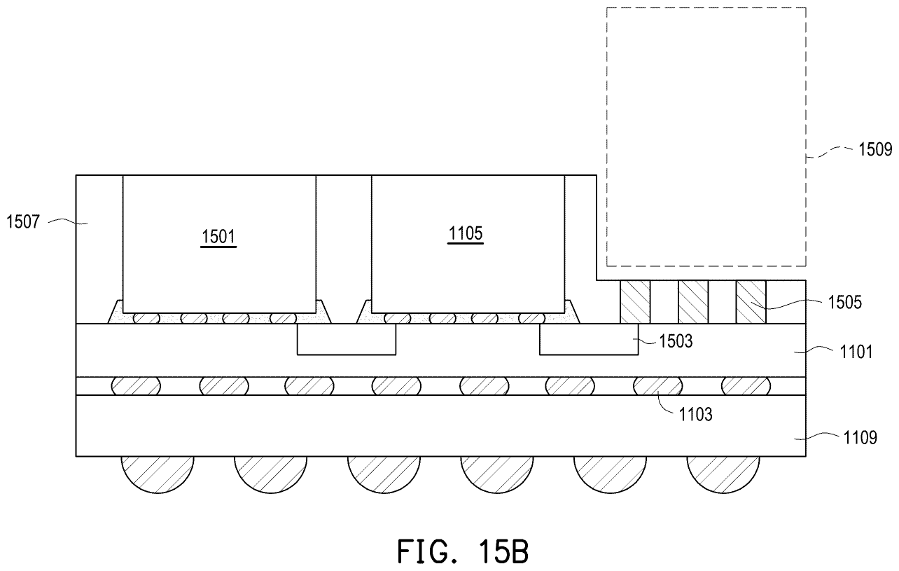

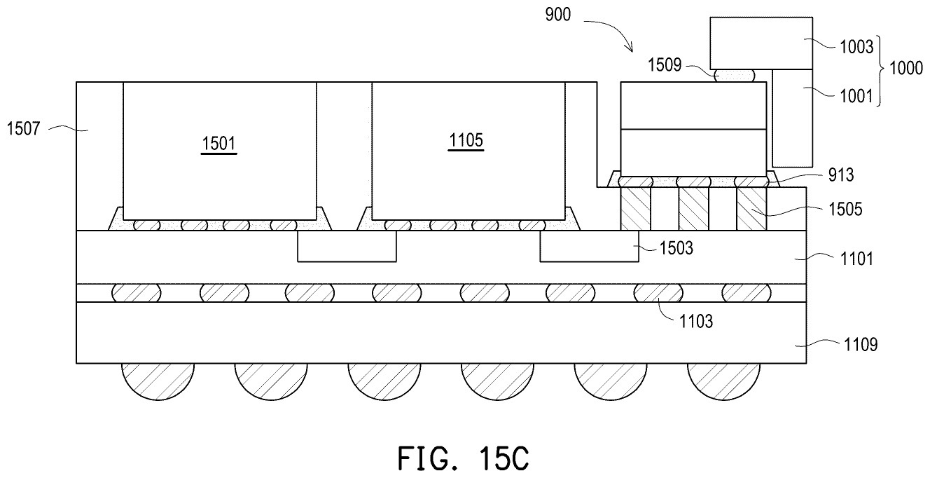

The first fiber array unit 1003 may be connected to the first optical package 900 so that the first lens 1013 is on an edge of the first optical package 900. In a particular embodiment the first fiber array unit 1003 is connected using, for example, an optical glue (not separately illustrated). However, in other embodiments the first fiber array unit 1003 may be connected using a fixing bracket (not illustrated in FIG. 10A but seen in FIG. 15C below), pins, clamps, force-fits, combinations of these, or the like. Any suitable process or materials may be utilized in order to attach the first fiber array unit 1003 to the first optical package 900.

FIG. 10B illustrates a close up view of the relative locations between the first lens 1013 and the first edge coupler 805 (within the second active layer 801). In this particular embodiment the first lens 1013 may be placed in order to be located a first distance D₁ away from the first edge coupler 805, wherein the first distance D₁ is less than about 5 μm. Additionally, the first lens 1013 may be placed such that a divergence angle θ is between about 5° and about 10°. However, any suitable location may be utilized.

By utilizing the first connecting unit 1000 with the first fiber array unit 1003 and the first lens 1013, the first optical package 900 with an edge coupler configuration can be obtained. As such, a high bandwidth can be obtained for advanced packaging scheme, such as a CoWoS scheme described herein. As such, a better performing device can be obtained.

Returning now to FIG. 10A, during operation (e.g., after subsequent packaging processes) the first fiber array unit 1003 receives the optical signals (represented in FIG. 10A by the lines labeled 1017) through the optical fibers and directs the optical signals 1017 towards the first mirror 1011 (using any combination of lenses and mirrors). The first mirror 1011 receives the optical signals 1017 and redirects them towards the first lens 1013, which collects the optical signals 1017 and directs the optical signals 1017 towards the first edge coupler 805.

The optical signals 1017 generated by the first optical package 900 may then be directed through the first edge coupler 805 towards the first lens 1013, which collects the optical signals 1017 and redirects the optical signals 1017 towards the first mirror 1011. The first mirror 1011 redirects the optical signals 1017 to the first fiber array unit 1003, where the optical signals 1017 enter the optical fibers and are transmitted out of the device.

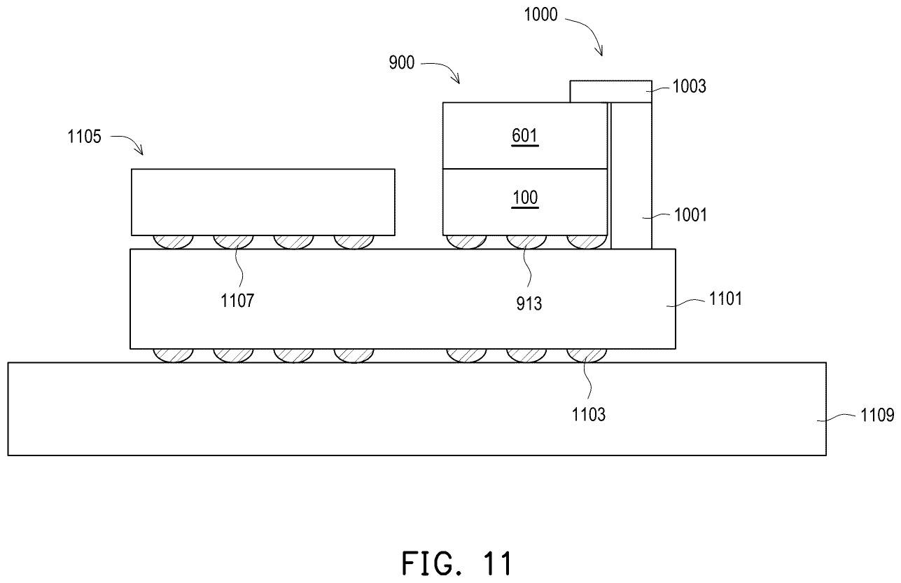

FIG. 11 illustrates that, once the first connecting unit 1000 (illustrated in a simplified form in FIG. 11) with the first fiber array unit 1003 and the first lens reflector module (LRM) 1001 have been mounted onto the first optical package 900, the first optical package 900 may be attached to an interposer substrate 1101 that is used to couple the first optical package 900 with other devices to form, for example, a chip-on-wafer-on-substrate (CoWoS®) device. In an embodiment the interposer substrate 1101 comprises a semiconductor substrate, third metallization layers, third through device vias (TDVs) (all of which are not illustrated for clarity), and second external connectors 1103. The semiconductor substrate may comprise bulk silicon, doped or undoped, or an active layer of a silicon-on-insulator (SOI) substrate. Generally, an SOI substrate comprises a layer of a semiconductor material such as silicon, germanium, silicon germanium, SOI, silicon germanium on insulator (SGOI), or combinations thereof. Other substrates that may be used include multi-layered substrates, gradient substrates, or hybrid orientation substrates.

Optionally, first active devices (not separately illustrated) may be added to the semiconductor substrate. The first active devices comprise a wide variety of active devices and passive devices such as capacitors, resistors, inductors and the like that may be used to generate the desired structural and functional requirements of the design for the semiconductor substrate. The first active devices may be formed using any suitable methods either within or else on the semiconductor substrate.

The third metallization layers are formed over the semiconductor substrate of the interposer substrate 1101 and the first active devices and are designed to connect the various devices to form functional circuitry. In an embodiment the third metallization layers of the interposer substrate 1101 are formed of alternating layers of dielectric (e.g., low-k dielectric materials, extremely low-k dielectric material, ultra low-k dielectric materials, combinations of these, or the like) and conductive material and may be formed through any suitable process (such as deposition, damascene, dual damascene, etc.). However, any suitable materials and processes may be utilized.

Additionally, at any desired point in the manufacturing process, the second TDVs may be formed within the semiconductor substrate and, if desired, one or more layers of the third metallization layers, in order to provide electrical connectivity from a front side of the semiconductor substrate to a back side of the semiconductor substrate. In an embodiment the second TDVs may be formed by initially forming through device via (TDV) openings into the semiconductor substrate and, if desired, any of the overlying third metallization layers (e.g., after the desired third metallization layer has been formed but prior to formation of the next overlying third metallization layer). The TDV openings may be formed by applying and developing a suitable photoresist, and removing portions of the underlying materials that are exposed to a desired depth. The TDV openings may be formed so as to extend into the semiconductor substrate to a depth greater than the eventual desired height of the semiconductor substrate.

Once the TDV openings have been formed within the semiconductor substrate and/or any third metallization layers, the TDV openings may be lined with a liner. The liner may be, e.g., an oxide formed from tetraethylorthosilicate (TEOS) or silicon nitride, although any suitable dielectric material may be used. The liner may be formed using a plasma enhanced chemical vapor deposition (PECVD) process, although other suitable processes, such as physical vapor deposition or a thermal process, may be used.

Once the liner has been formed along the sidewalls and bottom of the TDV openings, a barrier layer may be formed and the remainder of the TDV openings may be filled with first conductive material. The first conductive material may comprise copper, although other suitable materials such as aluminum, alloys, doped polysilicon, combinations thereof, and the like, may be utilized. The first conductive material may be formed by electroplating copper onto a seed layer, filling and overfilling the TDV openings. Once the TDV openings have been filled, excess liner, barrier layer, seed layer, and first conductive material outside of the TDV openings may be removed through a planarization process such as chemical mechanical polishing (CMP), although any suitable removal process may be used.

Once the TDV openings have been filled, the semiconductor substrate may be thinned until the second TDVs have been exposed. In an embodiment the semiconductor substrate may be thinned using, e.g., a chemical mechanical polishing process, a grinding process, or the like. Further, once exposed, the second TDVs may be recessed using, e.g., one or more etching processes, such as a wet etch process in order to recess the semiconductor substrate so that the second TDVs extend out of the semiconductor substrate.

In an embodiment the second external connectors 1103 may be placed and may be, e.g., a ball grid array (BGA) which comprises a eutectic material such as solder, although any suitable materials may be used. Optionally, an underbump metallization or additional metallization layers may be utilized between the third metallization layers and the second external connectors 1103. In an embodiment in which the second external connectors 1103 are solder bumps, the second external connectors 1103 may be formed using a ball drop method, such as a direct ball drop process. In another embodiment, the solder bumps may be formed by initially forming a layer of tin through any suitable method such as evaporation, electroplating, printing, solder transfer, and then performing a reflow in order to shape the material into the desired bump shape. Once the second external connectors 1103 have been formed, a test may be performed to ensure that the structure is suitable for further processing.

Once the interposer substrate 1101 has been formed, the first optical package 900 may be attached to the interposer substrate 1101. In an embodiment the first optical package 900 may be attached to the interposer substrate 1101 by aligning the first external connectors 913 with conductive portions of the interposer substrate 1101. Once aligned and in physical contact, the first external connectors 913 are reflowed by raising the temperature of the first external connectors 913 past a eutectic point of the first external connectors 913, thereby shifting the material of the first external connectors 913 to a liquid phase. Once reflowed, the temperature is reduced in order to shift the material of the first external connectors 913 back to a solid phase, thereby bonding the first optical package 900 to the interposer substrate 1101.

Optionally, a first underfill material (not separately illustrated) may be placed. The first underfill material may reduce stress and protect the joints resulting from the reflowing of the first external connectors 913. The first underfill material may be formed by a capillary flow process after the first optical package 900 has been attached.

FIG. 11 additionally illustrates a bonding of a second semiconductor device 1105 onto the interposer substrate 1101. In some embodiments, the second semiconductor device 1105 is an electronic integrated circuit (EIC) such as an XPU device. Of course, while the second semiconductor device 1105 is an XPU device in one embodiment, the embodiments are not restricted to the second semiconductor device 1105 being an XPU device. Rather, the second semiconductor device 1105 may be any suitable semiconductor device, such as a processor die, a memory die, or other type of functional die. In particular embodiments the second semiconductor device 1105 may be an a logic die, a 3DIC die, a CPU, a GPU, a SoC die, a MEMS die, a HBM die, combinations of these, or the like. Any suitable device with any suitable functionality, may be used, and all such devices are fully intended to be included within the scope of the embodiments.

In an embodiment the second semiconductor device 1105 may be bonded to the interposer substrate 1101 using, e.g., third external connections 1107. The third external connections 1107 may be conductive bumps (e.g., ball grid arrays, microbumps, etc.) or conductive pillars utilizing materials such as solder and copper. In an embodiment in which the third external connections 1107 are contact bumps, the third external connections 1107 may comprise a material such as tin, or other suitable materials, such as silver, lead-free tin, or copper. In an embodiment in which the third external connections 1107 are tin solder bumps, the third external connections 1107 may be formed by initially forming a layer of tin through such commonly used methods such as evaporation, electroplating, printing, solder transfer, ball placement, etc. Once a layer of tin has been formed on the structure, a reflow may be performed in order to shape the material into the desired bump shape.

Additionally, once the third external connections 1107 have been placed, the second semiconductor device 1105 is aligned with the interposer substrate 1101. Once aligned and in physical contact, the third external connections 1107 are reflowed by raising the temperature of the third external connections 1107 past a eutectic point of the third external connections 1107, thereby shifting the material of the third external connections 1107 to a liquid phase. Once reflowed, the temperature is reduced in order to shift the material of the third external connections 1107 back to a solid phase, thereby bonding the second semiconductor device 1105 to the interposer substrate 1101.

Optionally, an underfill material (not separately illustrated) may be placed. The underfill material may reduce stress and protect the joints resulting from the reflowing of the third external connections 1107 and the first external connectors 913. The underfill material may be formed by a capillary flow process after the first optical package 900 and the second semiconductor device 1105 are attached.

Once the second semiconductor device 1105 and the first optical package 900 have been bonded to the interposer substrate 1101, the interposer substrate 1101 may be bonded to a second substrate 1109 with, e.g., the second external connectors 1103. In an embodiment the second substrate 1109 may be a package substrate, which may be a printed circuit board (PCB) or the like. The second substrate 1109 may include one or more dielectric layers and electrically conductive features, such as conductive lines and vias. In some embodiments, the second substrate 1109 may include through-vias, active devices, passive devices, and the like. The second substrate 1109 may further include conductive pads formed at the upper and lower surfaces of the second substrate 1109.

The second external connectors 1103 may be aligned with corresponding conductive connections on the second substrate 1109. Once aligned the second external connectors 1103 may then be reflowed in order to bond the second substrate 1109 to the interposer substrate 1101. However, any suitable bonding process may be used to connect the interposer substrate 1101 to the second substrate 1109.

Additionally, the second substrate 1109 may be prepared for further connections by placing fourth external connections (not separately illustrated) on an opposite side of the second substrate 1109 from the first optical package 900. In an embodiment the fourth external connections may be formed using similar processes and materials as the second external connectors 1103. However, any suitable materials and processes may be utilized.

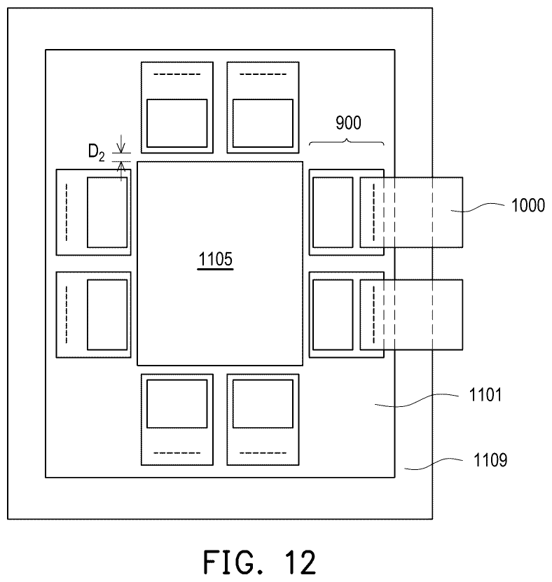

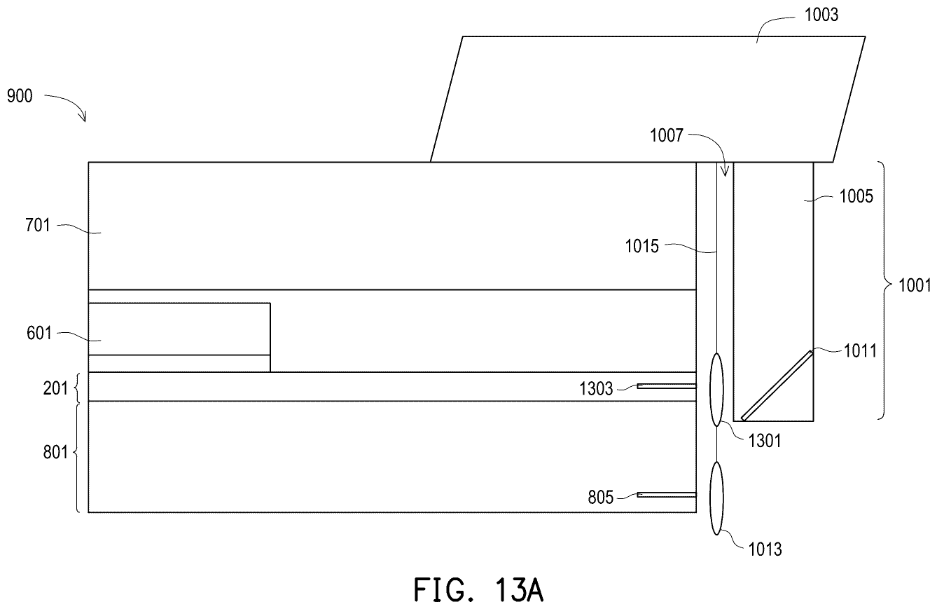

FIG. 12 illustrates a top down view of the optics on interposer (00I) device with the second substrate 1109 with the interposer substrate 1101, the second semiconductor device 1105, the first optical package 900 and the first connecting unit 1000. In an embodiment there may be multiple ones of the first optical package 900 connected with respective ones of the multiple ones of the first connecting unit 1000, such as eight first optical packages 900 connected to eight first connecting units 1000. However, any suitable number may be utilized.

Additionally, as can be seen in this view, the first optical packages 900 may be spaced apart from the second semiconductor device 1105 in order to minimize latency and improve the overall performance of the device. In a particular embodiment the first optical packages 900 may each be spaced a second distance D2 of less than about 100 μm, from the second semiconductor device 1105. However, any suitable distance may be utilized.

By utilizing the first connecting unit 1000 with the first optical package 900, the interposer substrate 1101, and the second substrate 1109, an optics on interposer (00I) with an edge coupler can be obtained. As such, a COUPE with an edge coupler (COUPE-EC) is available with an enhanced bandwidth. Additionally, this can be obtained for advanced packaging schemes, such as CoWoS schemes.

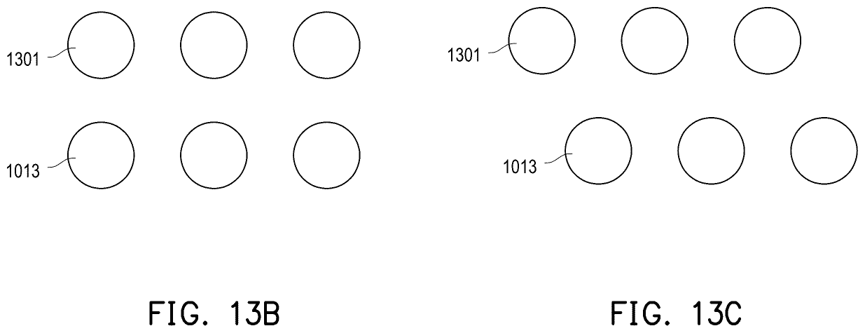

FIG. 13A illustrates another embodiment in which, instead of having one or more of the first lenses 1013 being located to send and receive the optical signals 1017 into just the second active layer 801, there may be second lenses 1301 located to also send and receive optical signals 1017 into and from an edge coupler (represented in FIG. 13A by the line labeled 1303) located within either the first active layer 201 (as illustrated in FIG. 13A), the first metallization layers 501, and/or the first bonding layer 505. In this embodiment the second lenses 1301 may be similar to the first lenses 1013, such as by being connected through a connection rod 1015, but are located at different distances from the first fiber array unit 1003. However, any suitable lens and any suitable method of connection may be utilized.

FIG. 13B illustrates multiples ones of the first lenses 1013 and the second lenses 1301. In the embodiment illustrated the first lenses 1013 (e.g., the lenses located in the lower levels of the first connecting units 1000) are vertically aligned with the second lenses 1301 (e.g., the lenses located in the upper levels of the first connecting units 1000). Additionally in this aligned embodiment the first mirrors 1011 may also be similarly aligned with each other in order to align with the first lenses 1013 and the second lenses 1301.

FIG. 13C illustrates another embodiment in which the first lenses 1013 and the second lenses 1301, instead of being aligned with each other as described above with respect to FIG. 13B, are shifted so as to be mis-aligned with each other. Additionally in this mis-aligned embodiment the first mirrors 1011 may also be mis-aligned with each other in order to align with the first lenses 1013 and the second lenses 1301. Any suitable arrangement of the first lenses 1013 and the second lenses 1301 may be utilized.

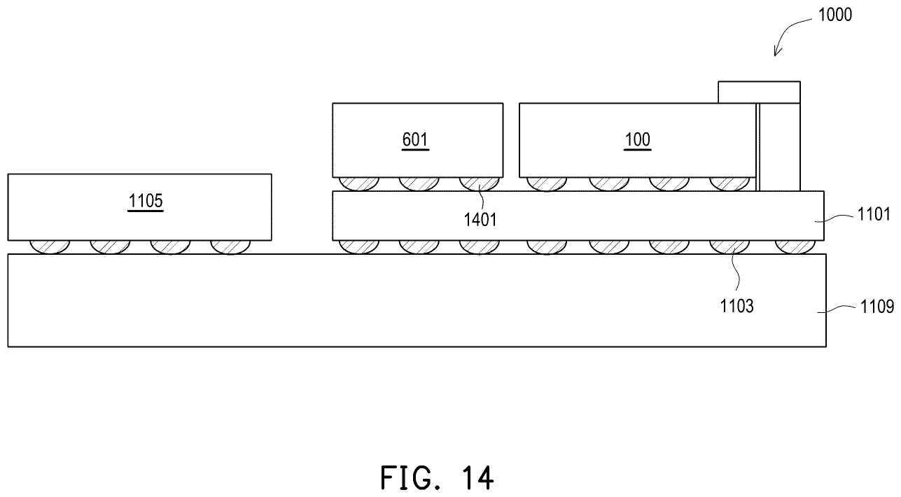

FIG. 14 illustrates another embodiment in which the first connecting unit 1000 is attached to the optical interposer 100 (shown in simplified form in FIG. 14 but which includes the second active layer 801 and the first external connectors 913). In this embodiment, however, the first semiconductor device 601 is not connected to the optical interposer 100. Rather, the first semiconductor device 601 is connected to the interposer substrate 1101 (through, e.g., fourth external connections 1401 similar to the third external connections 1107) and communicates with the optical interposer 100 through the interposer substrate 1101. Additionally in this embodiment the second semiconductor device 1105, instead of being bonded to the interposer substrate 1101, may be bonded to the second substrate 1109.

FIGS. 15A-15C illustrate yet another embodiment in which the first optical package 900 is connected to the interposer substrate 1101, but in which the first optical package 900 is connected after an encapsulation process. In this embodiment the second semiconductor device 1105 is bonded to the interposer substrate 1101 along with a third semiconductor device 1501 (which may be similar to the second semiconductor device 1105). Additionally, the second semiconductor device 1105 and the third semiconductor device 1501 may be connected through the interposer substrate 1101 through, for example, local silicon interconnect (LSI) dies 1503 located within, e.g., the metallization layers of the interposer substrate 1101. However, any suitable connections may be utilized.

Additionally in this embodiment, prior to an encapsulation, first connectors 1505 may be formed on the interposer substrate 1101. In an embodiment the first connectors 1505 may be conductive pillars such as copper pillars, although any suitable connector, such as solder connectors, or combination of connectors, may be utilized.

Once the second semiconductor device 1105 and the third semiconductor device 1501 have been attached, and the first connectors 1505 have been formed, the second semiconductor device 1105, the third semiconductor device 1501, and the first connectors 1505 are encapsulated with an encapsulant 1507. In an embodiment the encapsulant 1507 may be a material such as a molding compound placed using an injection molding process. Once in place, the molding compound may be cured and planarized. However, any suitable material and process may be used.

FIG. 15B illustrates a trimming of the encapsulant 1507 and formation of an opening through the encapsulant 1507 to expose the first connectors 1505. In an embodiment the opening may be formed using a saw (represented in FIG. 15B by the dashed box labeled 1509) or else may be formed using one or more masking and etching processes. However, any suitable method of forming the opening may be utilized.

FIG. 15C illustrates that, once the first connectors 1505 have been exposed, the first optical package 900 may be connected to the first connectors 1505. In an embodiment the first optical package 900 may be bonded as described above with respect to FIG. 11 (e.g., through the use of the first external connectors 913). However, any suitable bonding process may be utilized.

Additionally, the first connecting unit 1000 with the first fiber array unit 1003 and the first lens reflector module (LRM) 1001 and the first lens 1013 (shown in simplified form in FIG. 15C) are attached to the first optical package 900. In one embodiment the first fiber array unit 1003 and the first LRM 1001 of the first connecting unit 1000 are attached to each other prior to placement of the first optical package 900, while in other embodiments the first fiber array unit 1003 and the first LRM 1001 of the first connecting unit 1000 are attached to each other subsequent to placement of the first optical package 900.

In a particular embodiment the first connecting unit 1000 may be connected with the use of an adhesive 1509. In an embodiment the adhesive 1509 may be an adhesive or gel which may be used to help adhere the first fiber array unit 1003 to, e.g., the first support substrate 701 (shown in simplified form in FIG. 15C). However, any suitable method of adhering the first fiber array unit 1003 may be utilized.

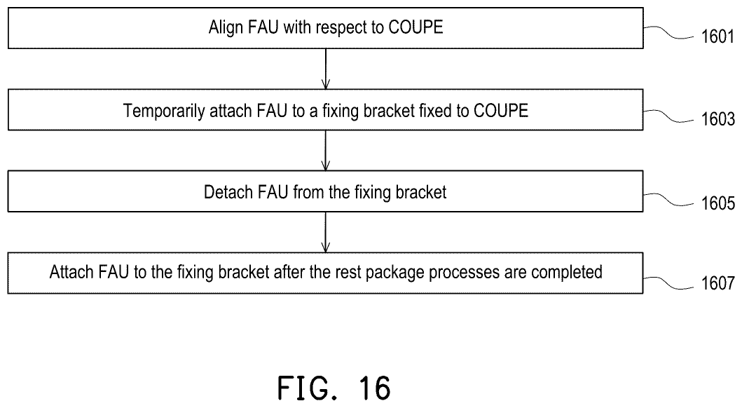

FIG. 16 illustrates another embodiment of the above described process of attaching the first connection unit 1000 with the first connection unit 1000 and the first lens reflector module 1001. In this embodiment the first fiber array unit 1003 of the first connection unit 1000 is first aligned with the first optical package 900 (e.g., a COUPE) in a first step 1601. In a second step 1603, the first fiber array unit 1003 with the first fiber array unit 1003 and the first lens reflector module 1001 are temporarily attached to the first optical package 900 using, e.g., the fixing bracket. In a third step 1605, first connection unit 1000 with the first fiber array unit 1003 and the first lens reflector module 1001 are detached from the fixing bracket, and a remainder of the packaging processes (e.g., any of the processes described above with respect to FIGS. 1-15C) are performed. Once the remainder of the packaging processes have been performed, the first connection unit 1000 with the first fiber array unit 1003 and the first lens reflector module 1001 may be reattached to the fixing bracket in order to connect the first connection unit 1000 with the first optical package 900 in a fourth step 1607. However, any suitable steps in any suitable order may be utilized.

By utilizing the first connecting unit 1000 with the first fiber array unit 1003 and the first lens 1013 as described herein, the first optical package 900 with an edge coupler configuration and without the use of lower-performing grating couplers can be obtained. As such, advanced packaging schemes such as CoWoS can be obtained that can achieve higher bandwidths than can be obtained with the use of grating couplers. With such a higher bandwidth, an overall better performance can be obtained for such devices.

In an embodiment, a method of manufacturing an optical device, the method including: providing a first optical package; and attaching a first connection unit to the first optical package, the first connection unit including: a fiber array unit; a first mirror; and a first lens located within a first space, wherein the first space is located between the first mirror and an edge coupler within the first optical package. In an embodiment the first connection unit further comprises a second lens located a different distance away from the fiber array unit than the first mirror. In and embodiment the first lens is aligned with the second lens. In and embodiment the first lens is mis-aligned with the second lens. In and embodiment the method further includes bonding the first optical package to an interposer substrate. In and embodiment the bonding the first optical package comprises bonding the first optical package to conductive pillars encapsulated within an encapsulant. In and embodiment the first lens is connected to the fiber array unit by a connection rod.

In another embodiment, a method of manufacturing an optical device includes: providing a first optical package with an edge coupler; and positioning a lens adjacent to the edge coupler, the lens being connected to a fiber array unit through a connection rod. In an embodiment the fiber array unit is attached to a lens reflector material and wherein a first mirror is located within the lens reflector material. In an embodiment the first optical package comprises an electronic integrated circuit bonded to an optical interposer. In an embodiment the method further includes: bonding the first optical package to an interposer substrate; and bonding a semiconductor device to the interposer substrate. In an embodiment the method further includes: detaching the fiber array unit from the first optical package; connecting the first optical package to an interposer substrate; and reattaching the fiber array unit to the first optical package after the connecting the first optical package. In an embodiment the method further includes: removing an encapsulant to expose conductive pillars; and bonding the first optical package to the conductive pillars. In an embodiment the method further includes positioning a second lens adjacent to a second edge coupler, the second lens being mis-aligned with the lens.

In yet another embodiment an optical device includes: an optical interposer with a first edge coupler; and a connection unit attached to the optical interposer, the connection unit including: a fiber array unit; a connection rod attached to the fiber array unit; and a first lens attached to the connection rod, the first lens surrounded by an ambient atmosphere. In an embodiment the connection unit further comprises a mirror aligned with the first lens and the first edge coupler. In an embodiment the connection unit further comprises a second lens, the first lens and the second lens being located at different distances from the fiber array unit. In an embodiment the first lens is aligned with the second lens. In an embodiment the first lens is mis-aligned with the second lens. In an embodiment the optical device further includes: an interposer substrate bonded to the optical interposer; and a semiconductor device bonded to the interposer substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An optical device comprising:
a first optical package; and
a first connection unit attached to the first optical package, the first connection unit comprising:
a fiber array unit;
a first mirror; and
a first lens located within a first space, wherein the first space is located between the first mirror and an edge coupler within the first optical package.

2. The optical device of claim 1, wherein the first lens is connected to a connection rod.

3. The optical device of claim 2, further comprising a second lens connected to the connection rod.

4. The optical device of claim 1, wherein the first lens is located less than 5 μm away from the edge coupler.

5. The optical device of claim 1, further comprising an interposer substrate bonded to the first optical package.

6. The optical device of claim 5, further comprising a semiconductor die bonded to the interposer substrate.

7. The optical device of claim 1, wherein the first lens is surrounded by air.

8. An optical device comprising:
a first optical package 900 with an edge coupler 805; and
a first lens 1013 positioned adjacent to the edge coupler 805, the first lens 1013 being connected to a fiber array unit 1003 through a connection rod 1017.

9. The optical device of claim 8, wherein the fiber array unit is attached to the first optical package.

10. The optical device of claim 8, wherein the first lens is located no further away from the edge coupler than about 5 μm.

11. The optical device of claim 8, wherein the first lens is located such that a divergence angle is between about 5° and about 10° C.

12. The optical device of claim 8, further comprising a second lens positioned adjacent to a second edge coupler.

13. The optical device of claim 12, wherein the second lens directly underlies the first lens.

14. The optical device of claim 12, wherein the second lens is offset from the first lens in a vertical direction.

15. An optical device comprising:
an optical interposer with a first edge coupler; and
a semiconductor die bonded to the optical interposer;
a support substrate attached to the semiconductor die and a gap-fill material;
a connection unit attached to the support substrate, the connection unit comprising:
a fiber array unit;
a first lens surrounded by an ambient atmosphere; and
a mirror aligned with the first lens and the first edge coupler.

16. The optical device of claim 15, wherein the first lens is less than 5 μm away from the first edge coupler.

17. The optical device of claim 15, wherein the connection unit further comprises a second lens, the first lens and the second lens being located at different distances from the fiber array unit.

18. The optical device of claim 17, wherein the first lens is aligned with the second lens.

19. The optical device of claim 17, wherein the first lens is mis-aligned with the second lens.

20. The optical device of claim 15, further comprising:
an interposer substrate bonded to the optical interposer; and
a semiconductor device bonded to the interposer substrate.
